(19) United States
(12) Patent Application Publication
(10) Pub. No.: US 2026/0107447 A1
(43) Pub. Date: Apr. 16, 2026

(54) THREE-DIMENSIONAL SEMICONDUCTOR MEMORY AND ELECTRONIC DEVICE THEREFOR

(71) Applicant: CXMT Corporation, Hefei (CN)

(72) Inventors: Ruisong Liu, Hefei (CN); Chao Lin, Hefei (CN)

(73) Assignee: CXMT Corporation, Hefei (CN)

(21) Appl. No.: 19/412,055

(22) Filed: Dec. 8, 2025

Related U.S. Application Data
(63) Continuation of application No. PCT/CN2025/112166, filed on Aug. 1, 2025.

(30) Foreign Application Priority Data
Aug. 9, 2024 (CN) 202411099297.1

(51) Int. Cl. H10B 12/00

(52) U.S. Cl. CPC H10B 12/482; H10B 12/315; H10B 12/488

(57) ABSTRACT

A three-dimensional semiconductor memory, includes a substrate, a plurality of active layers arranged in an array on the substrate, a plurality of bit lines, a plurality of storage nodes, and a shielding structure. Each of the bit lines is connected to one end of each of the active layers. The bit lines extend in a second direction, and are stacked on the substrate in a third direction. Each of the storage nodes is connected to the other end of each of the active layers. The shielding structure includes a body portion and a plurality of shielding portions. The shielding portions extend in the second direction. The body portion and the shielding portions each are formed of a conductive material, and the body portion is electrically connected to the shielding portions. At least one shielding portion is disposed between adjacent bit lines in the third direction.

### CROSS-REFERENCE TO RELATED APPLICATIONS

This application is a continuation of International Patent Application No. PCT/CN2025/112166, filed on August 1, 2025, which claims the benefit of Chinese Patent Application No. 202411099297.1, filed with the China National Intellectual Property Administration on August 9, 2024 and entitled “THREE-DIMENSIONAL SEMICONDUCTOR MEMORY AND ELECTRONIC DEVICE THEREFOR”. Each of the forgoing applications is herein incorporated by reference in its entirety for all purposes.

### BACKGROUND

As a dynamic memory develops toward higher integration density, a higher requirement is imposed on an arrangement manner of transistors in an array structure of the dynamic memory and the size of each of the transistors. However, due to limitations in manufacturing factors such as lithography machines and various electrical parasitic effects, there is a physical limit to the reduction of key sizes of the dynamic memory. Therefore, how to manufacture a chip with higher memory density on a wafer is a research direction of many researchers and semiconductor practitioners.

A three-dimensional dynamic random access memory (3D DRAM), especially a 3D DRAM including a multilayer horizontal cell (MHC), generally includes a structure in which multiple horizontally extending bit line structures are stacked on a substrate. In the vertical direction, there is parasitic capacitance between the stacked bit line structures. When the quantity of stacked layers is large, the parasitic capacitance tends to affect overall electrical performance of the memory structure, and in a serious case, causes a malfunction or a failure of the memory structure. Therefore, how to eliminate the parasitic capacitance in the stacked structures is a problem that needs to be solved urgently in the art.

### SUMMARY

Embodiments of the present disclosure relate to the field of semiconductor technologies, and in particular, to a three-dimensional semiconductor memory structure and an electronic device therefor.

Embodiments of the present disclosure provide a three-dimensional semiconductor memory, which at least helps reduce parasitic capacitance in a stacked structure, prevent interaction between different cells, and improve overall electrical performance of a storage node.

According to one aspect of the embodiments of the present disclosure, a three-dimensional semiconductor memory is provided, including: a substrate; multiple active layers arranged in an array on the substrate in a second direction and a third direction array; multiple bit lines extending in the second direction and stacked on the substrate in the third direction, the bit line connected to one end of the active layer in a first direction; multiple storage nodes, the storage node connected to the other end of the active layer in the first direction, and every two of the first direction, the second direction, and the third direction intersecting each other; and a shielding structure including a body portion and multiple shielding portions, the multiple shielding portions extending in the second direction, where the body portion and the shielding portion each is formed of a conductive material and electrically connected to each other; and at least one shielding portion is disposed between adjacent bit lines in the third direction.

According to another aspect of the embodiments of the present disclosure, an electronic device is further provided, including: a processor, and a memory, the memory coupled to the processor, and at least one of the memory and the processor including the three-dimensional semiconductor memory described in any embodiment of the present disclosure.

### BRIEF DESCRIPTION OF DRAWINGS

One or more embodiments are exemplified with the figures in the accompanying drawings corresponding to the one or more embodiments. These example descriptions are not intended to limit the embodiments, and unless specifically stated, no scale limitations are constituted by the figures in the accompanying drawings. To describe the technical solutions in the embodiments of the present disclosure or the conventional technologies more clearly, the accompanying drawings required by the embodiments are briefly described below. Clearly, the accompanying drawings in the following description show merely some embodiments of the present disclosure, and other drawings may be obtained by a person of ordinary skill in the art from these accompanying drawings without creative efforts.

FIG. 1 is a three-dimensional schematic diagram of a three-dimensional semiconductor memory according to an embodiment of the present disclosure;

FIG. 2 is a three-dimensional schematic diagram of a partial structure of a three-dimensional semiconductor memory according to an embodiment of the present disclosure;

FIG. 3 is a schematic diagram of a partial cross-section of the three-dimensional schematic diagram shown in FIG. 1;

FIG. 4 is an enlarged schematic diagram of a dashed part in the schematic diagram of the cross-section shown in FIG. 3;

FIG. 5 is a three-dimensional schematic diagram of a three-dimensional semiconductor memory according to another embodiment of the present disclosure;

FIG. 6 is a schematic diagram of a partial cross-section of a three-dimensional semiconductor memory according to another embodiment of the present disclosure;

FIGS. 7 to 18 are schematic diagrams of steps in a manufacturing method for a three-dimensional semiconductor memory according to an embodiment of the present disclosure; and

FIG. 19 is a schematic block diagram of a structure of an electronic device according to some embodiments of the present disclosure.

### DESCRIPTION OF EMBODIMENTS

The technical solutions of the present disclosure are further described below in detail with reference to the accompanying drawings and the embodiments. Although example implementations of the present disclosure are shown in the accompanying drawings, it should be understood that the present disclosure may be implemented in various forms without being limited by the implementations described herein. Instead, these implementations are provided to develop a more thorough understanding of the present disclosure and to fully convey the scope of the present disclosure to a person skilled in the art.

In the following paragraphs, the present disclosure is described more specifically by way of example with reference to the accompanying drawings. The advantages and features of the present disclosure will be clearer from the following description and claims. It should be noted that the accompanying drawings are presented in a highly simplified form and are not drawn to exact scale, and are merely intended to conveniently and clearly assist in describing the embodiments of the present disclosure.

It may be understood that meanings of "on", "over", and "above" in the present disclosure should be understood in the broadest sense, so that "on" means that it is "on" something with no intermediate feature or layer (that is, directly on something), and further includes the meaning that it is "on" something with an intermediate feature or layer.

In the embodiments of the present disclosure, the terms "first", "second", "third", and the like are intended to distinguish between similar objects but do not necessarily describe a specific order or sequence.

In the embodiments of the present disclosure, the term "layer" refers to a material part including a region having the thickness. The layer may extend over the whole of a lower or upper structure, or may have a range smaller than the range of the lower or upper structure. In addition, the layer may be a region of a homogeneous or heterogeneous continuous structure whose thickness is less than the thickness of a continuous structure. For example, the layer may be located between the top surface and the bottom surface of the continuous structure, or the layer may be located between any horizontal surface pair at the top surface and the bottom surface of the continuous structure. The layer may extend horizontally, vertically, and/or along an inclined surface. The layer may include multiple sublayers.

It should be noted that the technical solutions described in the embodiments of the present disclosure may be randomly combined when there is no conflict.

It may be learned from the background that a three-dimensional dynamic random access memory includes a multi-layer horizontal memory structure. In some structures, a bit line extends in the horizontal direction parallel to a substrate. Bit lines of memory structures at different layers are stacked in the vertical direction. The stacked bit lines are connected to a peripheral circuit by means of a lead structure of a staircase structure, to implement input or output of an electrical signal. When the quantity of stacked memory structures increases continuously, the quantity of stacked bit lines increases, so that parasitic capacitance between the stacked bit lines continues to accumulate. The parasitic capacitance interferes with signal transmission on bit lines, and in a severe case, causes a signal loss or a signal error, which affects overall electrical stability of the memory structures.

In a three-dimensional semiconductor memory provided in the embodiments of the present disclosure, a shielding structure is disposed, so as to effectively reduce the parasitic capacitance between the stacked bit lines, and improve electrical performance and electrical stability of the three-dimensional semiconductor memory. In the embodiments of the present disclosure, bit lines include not only bit lines in a memory array region, but also bit lines in a staircase region. The shielding structure is disposed between adjacent bit lines, so that parasitic capacitance between the adjacent bit lines is reduced, and signal transmission of a bit line signal is improved.

The embodiments of the present disclosure are described in detail below with reference to the accompanying drawings. However, it may be understood by a person of ordinary skill in the art that in the embodiments of the present disclosure, many technical details are provided to enable readers to better understand the embodiments of the present disclosure. However, the technical solutions claimed in the embodiments of the present disclosure may be implemented even without these technical details and various changes and modifications made based on the following embodiments.

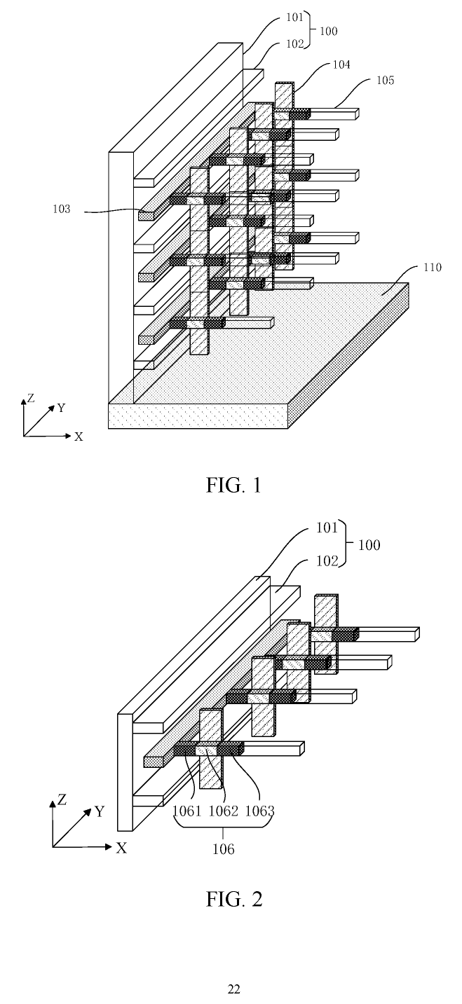

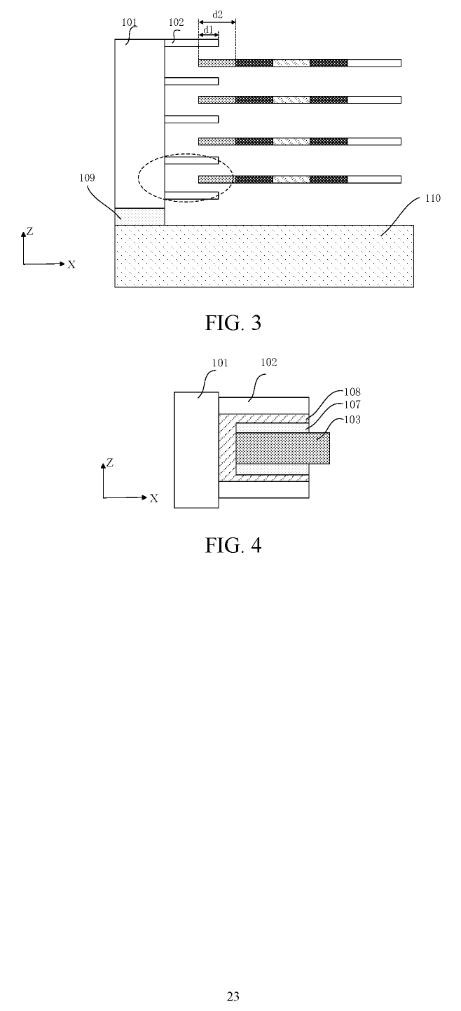

An embodiment of the present disclosure provides a three-dimensional semiconductor memory. The following describes in detail the three-dimensional semiconductor memory provided in an embodiment of the present disclosure with reference to the accompanying drawings. FIG. 1 is a schematic diagram of a three-dimensional structure of a three-dimensional semiconductor memory according to an embodiment of the present disclosure. FIG. 2 is a schematic diagram of a partial structure of a three-dimensional semiconductor memory according to an embodiment of the present disclosure. FIG. 3 is a partial cross-sectional view in a first direction X and a third direction Z in the schematic diagram of the three-dimensional structure of the three-dimensional semiconductor memory shown in FIG. 1. FIG. 4 is an enlarged schematic diagram of a dashed part in the cross-sectional view shown in FIG. 3.

Referring to FIGS. 1 to 4, a three-dimensional semiconductor memory is provided, including: a substrate 110; multiple active layers 106, where the multiple active layers 106 are arranged, in a second direction Y and the third direction Z respectively, in an array on the substrate 110; multiple bit lines 103, where each of the multiple bit lines 103 is connected to one end of each of multiple active layers 106 located at the same layer, and is electrically connected to the active layer 106; multiple storage nodes 105, where each of the multiple storage nodes 105 is connected to the other end that is of each of the multiple active layers 106 and that is away from each of the bit lines 103 in the first direction X; and a shielding structure 100, where the shielding structure 100 includes a body portion 101 and multiple shielding portions 102, the multiple shielding portions 102 extend in the second direction Y, and the shielding portions 102 are electrically connected to the body portion 101. At least one shielding portion 102 is disposed between adjacent bit lines 103 in the third direction Z.

As shown in FIG. 1, the three-dimensional semiconductor memory has a stacked structure formed on the substrate 110, that is, arranged in an array in the second direction Y and the third direction Z respectively. In this embodiment of the present disclosure, every two of the first direction X, the second direction Y, and the third direction Z intersect each other. A plane defined by the first direction X and the second direction Y is parallel to a surface of the substrate 110. In some embodiments, every two of the first direction X, the second direction Y, and the third direction Z may be perpendicular to each other. In actual application, an included angle between any two of the first direction X, the second direction Y, and the third direction Z is not 0° or 180°. For ease of description, an example in which every two of the first direction X, the second direction Y, and the third direction Z are perpendicular to each other is subsequently described in detail. The substrate 110 may be a material suitable for semiconductor processing, such as monocrystalline silicon, polysilicon, amorphous silicon, germanium, silicon carbide, silicon germanium, germanium on insulator (Germanium on Insulator, GOI for short), or silicon on insulator (Silicon on Insulator, SOI for short).

The bit lines 103 extend in the second direction Y parallel to the surface of the substrate 110. Each of the bit lines 103 is electrically connected to multiple active layers 106 located at the same layer. In some embodiments, the bit lines 103 are directly in contact with and electrically connected to the active layers 106. In some other embodiments, an interconnection layer, e.g., metal silicide, is further formed between each of the bit lines 103 and each of the active layers 106 for effectively reducing contact resistance. This is not specifically limited in this embodiment of the present disclosure. It may be understood that each of the bit lines 103 may be formed of a conductive material commonly employed in the art, such as doped Si, doped Ge, titanium nitride (TiN), tantalum nitride (TaN), tungsten (W), titanium (Ti), tantalum (Ta), copper (Cu), aluminium (Al), silver (Ag), gold (Au), tungsten silicide (WSi), cobalt silicide (CoSi), titanium silicide (TiSi), or a combination thereof.

As shown in FIGS. 1 and 2, the multiple active layers 106 are arranged in an array in the second direction Y and the third direction Z. Each of the active layers 106 is located on a side of each of the bit lines 103 in the first direction X. In this embodiment of the present disclosure, each of the active layers 106 is of a columnar or cylindrical structure extending in the first direction X. It may be understood that the active layer 106 may be in any other shape. This is not specifically limited in this embodiment of the present disclosure. As shown in FIG. 2, each of the active layers 106 includes a source region 1061, a channel region 1062, and a drain region 1063 sequentially arranged in the first direction X. In some embodiments, the source region 1061 and the drain region 1063 each include a doped element of a first type, and the channel region 1062 may include a doped element of a second type. A doped element of the first type and/or the second type may be an N-type element or a P-type element. The N-type element may be a group V element such as a phosphorus (P) element, a bismuth (Bi) element, an antimony (Sb) element, or an arsenic (As) element. The P-type element may be a group III element such as a boron (B) element, an aluminium (Al) element, a gallium (Ga) element, or an indium (In) element. It may be understood that a doping type of each of the source region 1061 and the drain region 1063 may be different (that is, forming a junction structure) from or the same (that is, forming a junction-less structure) as a doping type of the channel region 1062. This is not specifically limited in this embodiment of the present disclosure. The material of the active layer 106 includes monocrystalline silicon, polysilicon, single-crystal silicon-germanium (SiGe), or an oxide semiconductor material. The oxide semiconductor material is any one or a combination of two or more of In₂O₃ (indium oxide), ZnO (zinc oxide), IZO (indium zinc oxide), IGZO (indium gallium zinc oxide), IZTO (indium tin zinc oxide), or ZnON (zinc oxynitride).

As shown in FIGS. 1 to 3, each of the storage nodes 105 is located at the other end that is of each of the active layers 106 and that is away from each of the bit lines 103 in the first direction. Each of the storage nodes 105 is electrically connected to the other end of each of the active layers 106, that is, electrically connected to the drain region 1063. Each of the storage nodes 105 is correspondingly connected to one active layer 106. In some embodiments, each of the storage nodes 105 includes a capacitor, and the capacitor includes a columnar capacitor or a cylindrical capacitor. The capacitor includes a capacitor bottom electrode, a capacitor dielectric layer, and a capacitor top electrode. The capacitor bottom electrode is electrically connected to the drain region 1063 of the active layer 106, and the capacitor dielectric layer is located between the capacitor bottom electrode and the capacitor top electrode. The material of the capacitor bottom electrode or the capacitor top electrode includes a metal material, e.g., Ti, Ta, W, Cu, Al, TiN, TaN, or a combination thereof. The capacitor dielectric layer may be a high dielectric constant material, e.g., hafnium oxide, zirconium oxide, aluminium oxide, lanthanum oxide, titanium oxide, tantalum oxide, niobium oxide, or strontium titanate. In some embodiments, the storage node 105 may alternatively be a storage node of another type, such as a phase change memory or a resistive memory.

As shown in FIG. 1, the three-dimensional semiconductor memory further includes multiple word lines 104. The multiple word lines 104 extend in the third direction Z, and each of the word lines 104 is corresponding to the multiple active layers 106 stacked in the third direction Z. Specifically, the channel region 1062 of each of the active layers 106 is corresponding to one word line 104, and a gate dielectric layer (not shown in the figure) is disposed between the channel region 1062 and a corresponding word line 104. As shown in FIGS. 1 and 2, each of the word lines 104 extends in the third direction and is located on one side of the channel region 1062. In some embodiments, a word line structure formed on the other side of the channel region is further included, that is, a dual-word-line structure is formed. Alternatively, the word line surrounds an outer side of the channel region 1062 to form a word-line-gate-all-around (GAA) transistor. In some embodiments, the word line 104 may further penetrate through stacked channel regions 1062 to form a channel-all-around (CAA) transistor. The material of the word line 104 is any one of metal tungsten, tantalum, molybdenum, titanium nitride, or tantalum nitride, to form a metal gate line. In some other embodiments, the material of the word line is doped polysilicon. Because an energy gap of the polysilicon is close to that of the material of the active layer serving as a channel, and a work function of the polysilicon may be changed by controlling a doping concentration, which help reduce a threshold voltage between a gate and the channel region of the active layer. A doped element type of the doped polysilicon is the same as or different from a doped element type of the channel region of the active layer.

In this embodiment of the present disclosure, the shielding structure 100 includes the body portion 101 and the multiple shielding portions 102 that are each formed of a conductive material. The multiple shielding portions 102 extend in the second direction Y. At least one shielding portion 102 is disposed between adjacent bit lines 103 in the third direction Z. To be specific, the shielding portion 102 formed of a conductive material is inserted between the bit lines 103, so that the two bit lines 103 are shielded away from each other, and parasitic capacitance between the bit lines 103 is reduced. Although parasitic capacitance between each of the bit lines 103 and the shielding portion 102 is increased, in fact, a gain of inserting the shielding portion 102 to reduce the parasitic capacitance between the bit lines 103 is greater than a gain brought by the parasitic capacitance between the bit line 103 and the shielding portion 102. In other words, the gain of reducing the parasitic capacitance between the bit lines 103 is more significant.

As shown in FIGS. 1 to 3, the shielding structure 100 includes the body portion 101 and the multiple shielding portions 102. The multiple shielding portions 102 are electrically connected separately to the body portion 101, and the shielding portions 102 extend in the second direction Y. As shown in FIG. 3, there is an overlapping part between a projection of each of the shielding portions 102 on the substrate 110 and a projection of each of the bit lines 103 on the substrate 110. The length of the overlapping part in the first direction X is d1, and the length of each of the bit lines 103 in the first direction X is d2. d1 is greater than or equal to d2/2. In other words, the shielding portion 102 covers the bit line 103 by at least half of the length of the bit line 103 in the first direction X. In this embodiment of the present disclosure, to implement effective electrical isolation between stacked bit lines, and reduce the parasitic capacitance between the bit lines, the length of the bit line effectively covered with the shielding portion 102 needs to be greater than or equal to half of the actual length of the bit line. When the coverage length is less than half of the actual length, relatively large parasitic capacitance is still formed between adjacent bit lines, and the shielding portion cannot implement effective electrical isolation. In some embodiments, d1 is greater than or equal to d2. To be specific, the length of the bit line effectively covered with the shielding portion 102 is greater than or equal to the actual length of the bit line, so that complete electrical isolation can be implemented, thereby improving electrical performance of the three-dimensional semiconductor memory. It may be understood that there is a region in which the shielding portion 102 is opposite to the bit line 103, and the shielding portion 102 and the bit line 103 each are formed of a conductive material. In this case, there is also parasitic capacitance between the shielding portion 102 and the bit line 103. To effectively reduce the parasitic capacitance between bit lines and prevent the parasitic capacitance between the shielding portion 102 and the bit line 103 from affecting the three-dimensional semiconductor memory, in this embodiment of the present disclosure, d1 may be greater than or equal to d2/2, and less than d2.

In some embodiments, an insulating dielectric layer 109 is further disposed between the body portion 101 and the substrate 110. As shown in FIG. 3, the body portion 101 is electrically isolated from the substrate 110 by means of the insulating dielectric layer 109. When the body portion 110 is electrically connected to a fixed potential end, a potential of the substrate 110 is not affected, thereby avoiding interference to an operating potential of a three-dimensional memory structure. The material of the insulating dielectric layer 109 is at least one of silicon oxide, silicon nitride, silicon oxynitride, and a low-k dielectric material.

In some embodiments, the thickness of each of the shielding portions 102 in the third direction Z is less than or equal to the thickness of each of the bit lines 103 in the third direction Z. To improve memory density of the three-dimensional semiconductor memory, the thickness of a spacing between stacked memory structures is less than the thickness of each of the memory structures itself, and the shielding portion 102 is disposed at an interval between the bit lines 103 (that is, between the memory structures) in the third direction Z. In this case, the thickness of the shielding portion 102 in the third direction Z is less than or equal to the thickness of the bit line 103 in the third direction Z, so that the memory density of the three-dimensional semiconductor memory can be improved, and integration density of the memory device can be improved.

In some embodiments, the length of the shielding portion 102 is greater than or equal to the length of the bit line 103 in the second direction Y. As shown in FIGS. 1 and 2, to implement effective electrical isolation between adjacent bit lines 103, the shielding portion 102 may cover the bit line extending in the second direction Y by the entire length of the bit line. The bit line 103 is connected to a peripheral circuit by means of a staircase structure (not shown) electrically connected to the bit line 103, so as to implement input or output of a signal. The staircase structure may extend in the first direction X or the second direction Y. This is not specifically limited in this embodiment of the present disclosure.

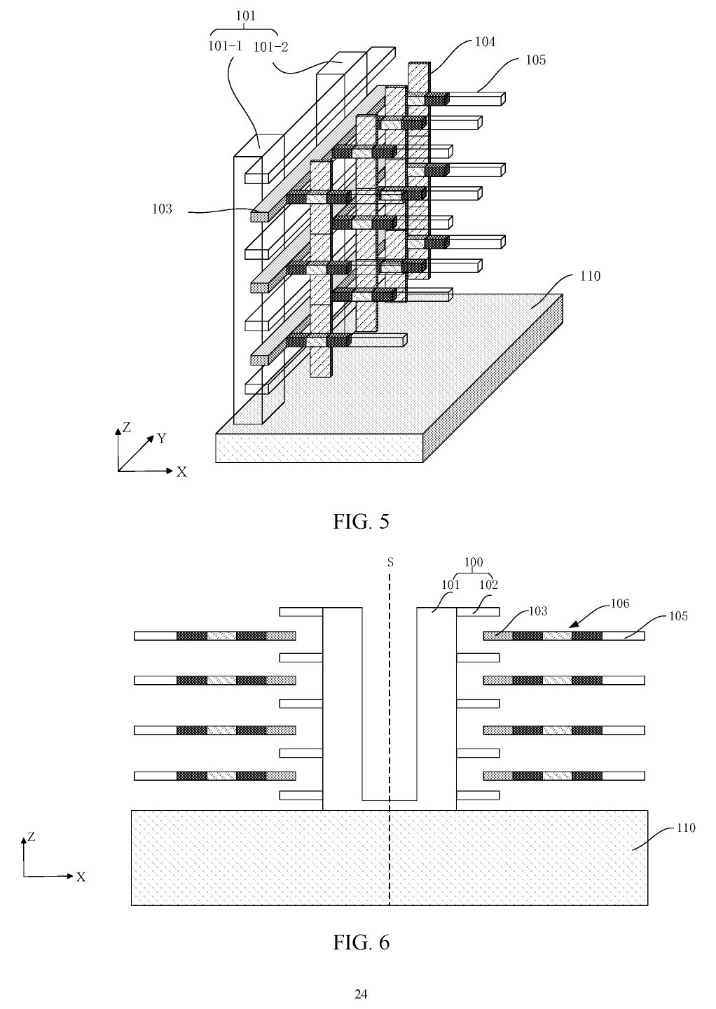

As shown in FIG. 1, the body portion 101 extends in the second direction Y and the third direction Z to form a structure in the shape of a flat plate. The multiple shielding portions 102 are disposed on one side of the body portion 101. The body portion 101 is connected to the fixed potential end by means of a wire (not shown). The shielding portions 102 are electrically connected to the body portion 101, and are connected to the fixed potential end by means of the body portion 101, e.g., may be grounded, so as to implement electrical shielding of the stacked bit lines 103. As shown in FIGS. 1 and 2, the body portion 101 extends in the second direction Y, and has a relatively large relative area with the multiple stacked bit lines 103. Therefore, relatively large parasitic capacitance tends to be generated. In some embodiments, as shown in FIG. 5, in the second direction Y, the length of the body portion 101 is less than the length of each of the bit lines 103. The length of the body portion 101 in the second direction Y is shortened, so that parasitic capacitance between the body portion 101 and the bit line 103 can be effectively reduced, and impact on electrical performance of the memory can be reduced. In some embodiments, as shown in FIG. 5, multiple sub-body portions, 101-1 and 101-2, may be included. The multiple sub-body portions, 101-1 and 101-2, extend in the third direction Z, and are arranged at intervals in the second direction Y. Each of the sub-body portions, 101-1 and 101-2, is electrically connected to the multiple shielding portions 102. In some embodiments, when the multiple sub-body portions are included, each of the sub-body portions and each of the word lines 104 are staggered in the first direction X. In this way, parasitic capacitance between the body portion and each of the word lines can be reduced, and an electrical signal on the word line is prevented from being affected by the body portion at a ground potential, so as to improve stability of the electrical signal on the word line.

As shown in FIG. 6, in some embodiments, multiple shielding portions 102 are respectively located two opposite sides of the body portion 101 in the first direction X. It may be understood that the multiple shielding portions 102 located at two sides of the body portion 101 may be mirror-symmetrical about a symmetry axis S. To be specific, a three-dimensional semiconductor memory structure is mirror-symmetrical about the symmetry axis S, and the mirror-symmetrical three-dimensional semiconductor memory structure shares the same body portion 101. In this case, a cross-section of the body portion 101 on the plane where the first direction X and the third direction Z are located is U-shaped. In some embodiments, separate body portions 101 may also be formed, and are connected respectively to different three-dimensional semiconductor memory structures. Alternatively, an integrated body portion 101 may be formed, and the different three-dimensional semiconductor memory structures share the same body portion 101. This is not specifically limited in this embodiment of the present disclosure.

In some embodiments, the body portion 101 and the multiple shielding portions 102 are of an integrated structure, that is, formed in the same process step. The body portion 101 and the multiple shielding portions 102 each are formed of a conductive material. The conductive material includes at least one of Ti, Ta, W, Cu, Al, TiN, and TaN. In this embodiment of the present disclosure, the conductive material is TiN. In some embodiments, the material of each of the bit lines 103 and the material of each of the shielding portions 102 may be the same, such as TiN.

In some embodiments, a second dielectric layer 108 is further disposed between the bit lines 103 and the body portion 101, and a first dielectric layer 107 and the second dielectric layer 108 are further disposed between the bit lines 103 and the shielding portions 102. FIG. 4 is an enlarged schematic diagram of a dashed part in the cross-sectional view shown in FIG. 3. As shown in FIG. 4, a stacked structure of the first dielectric layer 107 and the second dielectric layer 108 is further disposed between the bit line 103 and the shielding portion 102 in the third direction. The material of the first dielectric layer 107 is at least one of silicon oxide, silicon nitride, silicon oxynitride, and a low-k dielectric material; and/or, the material of the second dielectric layer 108 is at least one of silicon oxide, silicon nitride, silicon oxynitride, and a low-k dielectric material. In this embodiment of the present disclosure, to reduce the parasitic capacitance between the bit line 103 and the body portion 101 and the parasitic capacitance between the bit line 103 and the shielding portion 102, optionally, the second dielectric layer 108 is made of a low-k dielectric material. For example, the low-k dielectric constant material may be but is not limited to one or a combination of two or more of SiOH, SiOCH, FSG (fluorosilicate glass), BSG (borosilicate glass), PSG (phosphosilicate glass), and BPSG (borophosphosilicate glass).

In conclusion, the three-dimensional semiconductor memory is provided in the embodiments of the present disclosure, including: the substrate; the multiple active layers located on the substrate, where the multiple active layers are arranged in an array on the substrate; the multiple bit lines, where each of the multiple bit lines is connected to one end of each of the active layers, the multiple bit lines extend in the second direction, and the multiple bit lines are stacked on the substrate in the third direction; and the shielding structure, where the shielding structure includes the body portion and the multiple shielding portions, the shielding portions extend in the second direction, the body portion and the shielding portions each are formed of a conductive material, and the body portion is electrically connected to the shielding portions. At least one shielding portion is disposed between adjacent bit lines in the third direction. In the embodiments of the present disclosure, the shielding portions are formed between stacked bit lines. The shielding portions are electrically connected to the body portion, and are connected to the fixed potential end by means of the body portion, so as to implement electrical isolation between the stacked bit lines, reduce the parasitic capacitance between the bit lines, and further reduce signal interference between adjacent bit lines, thereby improving overall electrical performance of a stacked device.

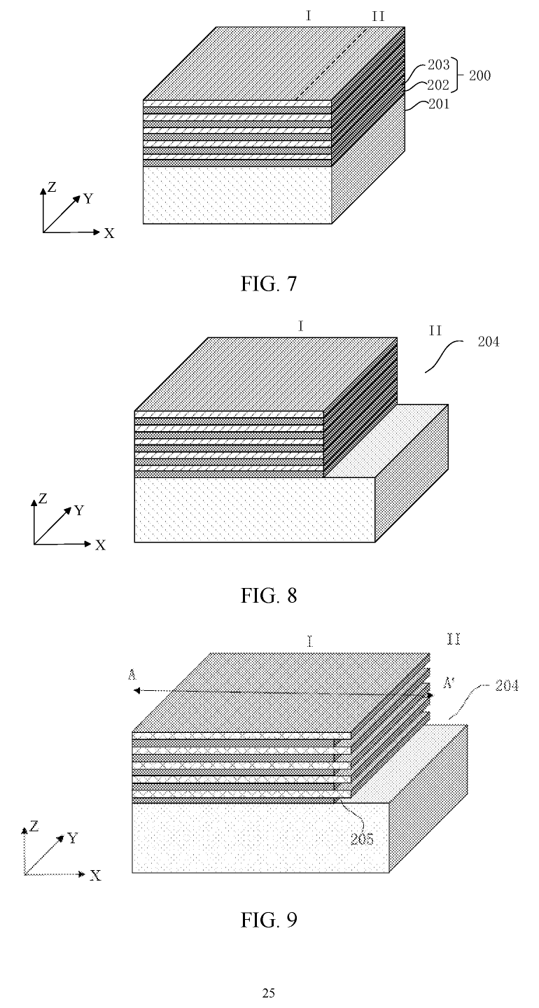

An embodiment of the present disclosure further provides a manufacturing method for a three-dimensional semiconductor memory. The following describes in detail the manufacturing method for a three-dimensional semiconductor memory provided in an embodiment of the present disclosure with reference to the accompanying drawings. FIGS. 7 to 18 are partial schematic diagrams corresponding to steps in the manufacturing method for a semiconductor structure according to an embodiment of the present disclosure. The following describes in detail the manufacturing method for a semiconductor structure according to an embodiment of the present disclosure with reference to FIGS. 7 to 18.

As shown in FIG. 7, a substrate 201 is provided. A multilayer stacked structure 200 stacked in a third direction Z is formed on the substrate 201. The stacked structure 200 includes a first stacking layer 202 and a second stacking layer 203 stacked in sequence in the third direction Z. The material of the substrate 201 is monocrystalline silicon, polysilicon, amorphous silicon, germanium, silicon carbide, silicon germanium, germanium on insulator (Germanium on Insulator, GOI for short), silicon on insulator (Silicon on Insulator, SOI for short), or the like. In some embodiments, the material of the substrate is selected as a monocrystalline silicon material. N-type or P-type doping processing and annealing treatment are performed on the monocrystalline silicon material, to form an N-type or P-type substrate 201. An N-type element may be a group V element such as a phosphorus (P) element, a bismuth (Bi) element, an antimony (Sb) element, or an arsenic (As) element. A P-type element may be a group III element such as a boron (B) element, an aluminium (Al) element, a gallium (Ga) element, or an indium (In) element. In this embodiment of the present disclosure, before the stacked structure 200 is formed on the substrate 201, a surface of the substrate 201 may be preprocessed to remove impurities or a natural oxide layer on the surface. The first stacking layer 202 may be formed of at least one of or include at least one of silicon, germanium, silicon germanium, silicon oxide, silicon nitride, silicon oxynitride, and the like. For example, the first stacking layer 202 may be formed of silicon oxide. The second stacking layer 203 may be formed of at least one of or include at least one of silicon, germanium, silicon germanium, silicon oxide, silicon nitride, silicon oxynitride, and the like. For example, the second stacking layer 203 may be formed of silicon nitride. In some embodiments, the first stacking layer 202 and the second stacking layer 203 each may be formed through an epitaxial process or a deposition process. It may be understood that, in the same etching condition, the first stacking layer 202 has a relatively high etching selectivity ratio with the second stacking layer 203, e.g., greater than or equal to 10:1, thereby facilitating formation of a three-dimensional stacked structure. In addition, as shown in FIG. 7, the stacked structure 200 includes a first region I and a second region II distributed in a first direction X. The first region is configured to subsequently form a transistor and a storage node of a three-dimensional memory, and the second region II is configured to form a bit line structure and a shielding structure.

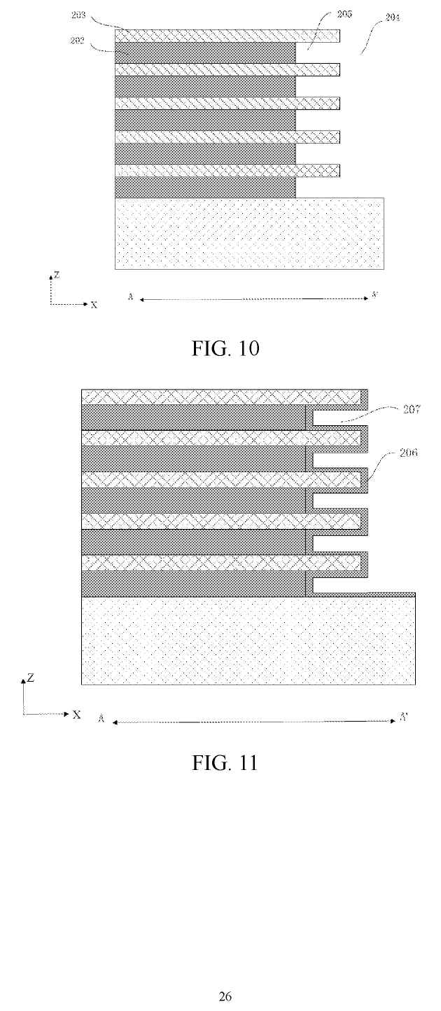

Patterned processing is performed on the stacked structure 200. The stacked structure in the second region II is removed, to form an opening 204 exposing an upper surface of the substrate 201. As shown in FIG. 8, a mask layer (not shown) is formed over the stacked structure 200, and patterned processing is performed on the stacked structure 200. The patterned processing includes dry etching, wet etching, or a combination thereof. After patterned processing, the stacked structure in the second region II is removed to form the opening 204, and the opening 204 exposes the upper surface of the substrate 201. As shown in FIG. 9, lateral selective etching is performed on the stacked structure 200 in the first region I through the opening 204, to remove a part of the first stacking layer 202 and form multiple first grooves 205. The multiple first grooves 205 are located between the second stacking layers 203 or between the second stacking layer 203 and the substrate 201. The first grooves 205 are communicated with the opening 204. FIG. 10 is a cross-sectional view of FIG. 9 in an A-A’ direction. As shown in FIG. 10, a part of the first stacking layer 202 is etched out through a lateral etching process. It may be understood that there is a relatively high etching selectivity ratio (e.g., greater than or equal to 10:1) between the first stacking layer 202 and the second stacking layer 203 and between the first stacking layer 202 and the substrate 201. Therefore, when the first stacking layer 202 is etched out, the second stacking layer 203 and/or the substrate 201 is etched by a minimal amount or basically not etched.

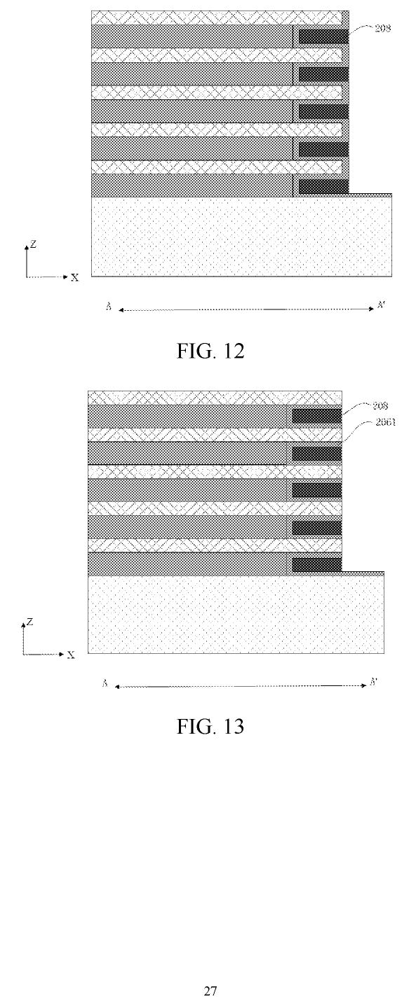

As shown in FIG. 11, a first dielectric material layer 206 is deposited in the opening 204 or the multiple first grooves 205 communicated with the opening 204 through a process such as chemical vapor deposition (Chemical Vapor Deposition, CVD for short), physical vapor deposition (Physical Vapor Deposition, PVD for short), or atomic Layer deposition (Atomic Layer Deposition, ALD for short). The first dielectric material layer 206 may further cover the upper surface of the exposed substrate 201. The material of the first dielectric material layer 206 is at least one of silicon oxide, silicon nitride, silicon oxynitride, and a low-k dielectric material. As shown in FIG. 11, the first dielectric material layer 206 located in each of the first grooves 205 covers an exposed surface of each of the first stacking layer 202 and the second stacking layer 203. The first dielectric material layer 206 located in the first groove 205 forms a second groove 207, and the second groove 207 is communicated with the opening 204. As shown in FIG. 11, a sacrificial layer 208 is filled in the second groove 207. For example, the sacrificial layer may be formed through the chemical vapor deposition process, and the sacrificial layer outside the second groove 207 is removed through a dry etching process or a wet etching process, so that the sacrificial layer 208 is filled in the second groove 207. In some embodiments, the material of the sacrificial layer 208 is at least one of silicon oxide, silicon nitride, silicon oxynitride, a low-k dielectric material, and polysilicon. In this embodiment of the present disclosure, the sacrificial layer 208 has a relatively high etching selectivity ratio (e.g., greater than or equal to 10:1) with each of the first stacking layer 202, the second stacking layer 203, and the first dielectric material layer 206. For example, the material of the sacrificial layer 208 is polysilicon. As shown in FIG. 12, a patterning process is adopted to remove the first dielectric material layer 206 on a side of the second stacking layer 203 in the first direction X, and the remaining first dielectric material layer forms a first dielectric layer 2061. In some embodiments, as shown in FIG. 13, a part of the sacrificial layer 208 may be further removed in the first direction X, so that the sacrificial layer 208 is flush with the formed first dielectric layer 2061 in the vertical direction. Optionally, the first dielectric material layer and the sacrificial layer may be separately removed by performing different removal steps.

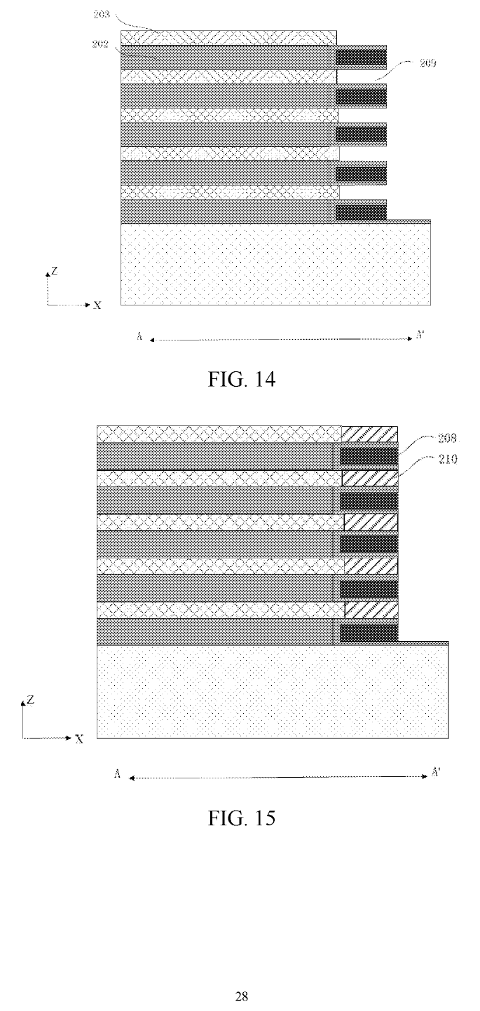

As shown in FIG. 14, lateral etching is performed, e.g., through the wet etching process, on the second stacking layer 203 in the first direction X through the opening 204, to remove a part of the second stacking layer, and form multiple third grooves 209. The third grooves 209 are located between adjacent first dielectric layers 2061, and are communicated with the opening 204. In some embodiments, the length of each of the third grooves 209 in the first direction may be less than or equal to the length of the first dielectric layer 2061 in the first direction. It may be understood that duration of the lateral etching process and the length of the third groove 209 formed through etching may be determined based on the length of a bit line covered with a finally formed shielding portion. As shown in FIG. 15, a bit line material layer is filled in the third groove 209 to form a bit line layer 210. For example, the sacrificial layer may be formed through the chemical vapor deposition process, and the bit line layer outside the third groove 209 is removed through the dry etching process or the wet etching process, so that the bit line layer 210 is filled in the third groove 209. In some embodiments, the bit line layer 210 may be formed of a conductive material commonly employed in the art, e.g., doped Si, doped Ge, titanium nitride (TiN), tantalum nitride (TaN), tungsten (W), titanium (Ti), tantalum (Ta), copper (Cu), aluminium (Al), silver (Ag), gold (Au), tungsten silicide (WSi), cobalt silicide (CoSi), titanium silicide (TiSi), or a combination thereof.

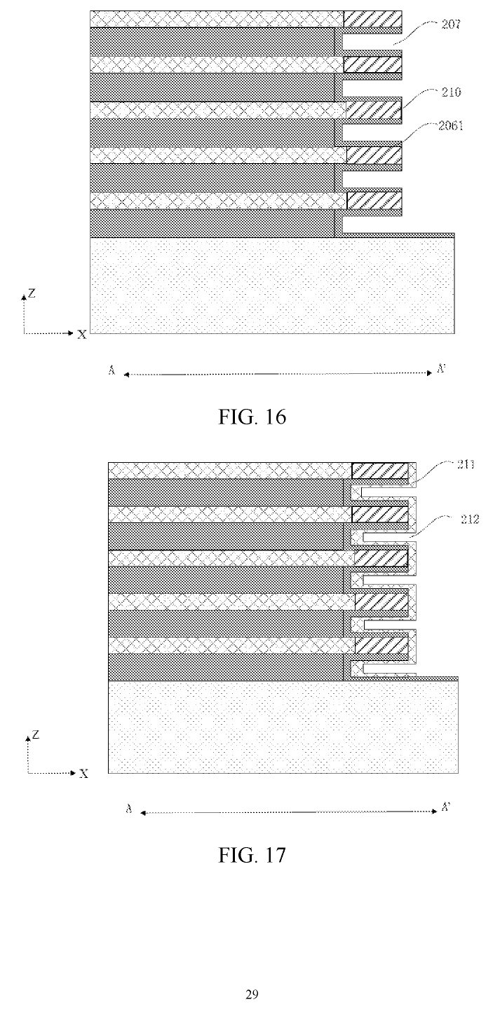

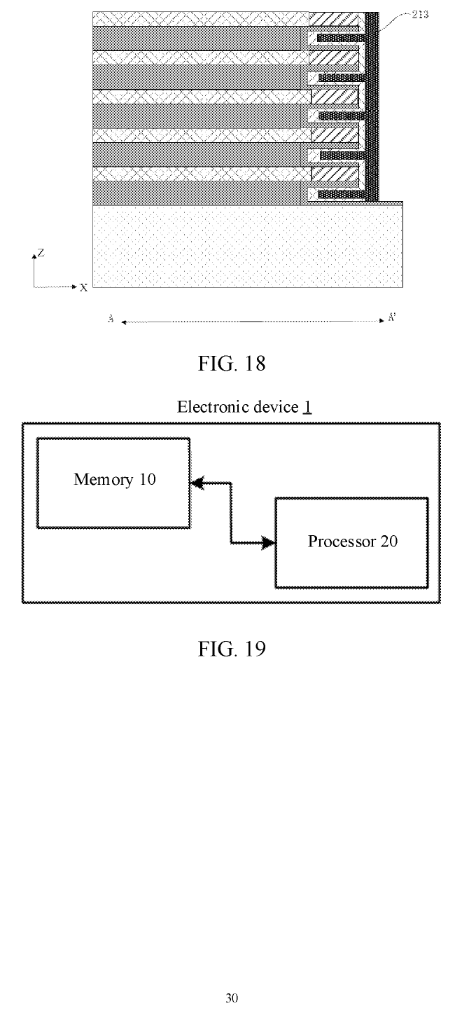

After the bit line layer 210 is formed, the sacrificial layer 208 is removed through a selective etching process. As shown in FIG. 16, the sacrificial layer 208 is selectively etched through the opening 204 to expose the second groove 207. The wet etching process may be adopted to perform lateral etching on the sacrificial layer 208. Because the sacrificial layer 208 has a high etching selectivity ratio (e.g., greater than or equal to 10:1) with each of the first dielectric layer 2061 and the bit line layer 210, when the sacrificial layer 208 is etched out, the first dielectric layer 2061 and the bit line layer 210 are etched by a relatively small amount or not etched. As shown in FIG. 17, a second dielectric material layer 211 is deposited in the opening 204 and the multiple second grooves 207 communicated with the opening 204 through a process such as chemical vapor deposition, physical vapor deposition, or atomic layer deposition. The material of the second dielectric material layer 211 is at least one of silicon oxide, silicon nitride, silicon oxynitride, and a low-k dielectric material. In this embodiment of the present disclosure, to reduce parasitic capacitance between a bit line and the shielding structure, a low-k dielectric material may be selected as the second dielectric material layer. As shown in FIG. 18, a shielding material layer 213 is formed on a surface of the formed second dielectric layer 211, and the material of the shielding material layer 213 includes at least one of Ti, Ta, W, Cu, Al, TiN, and TaN.

At least some embodiments of the present disclosure further provide an electronic device. FIG. 19 is a schematic block diagram of a structure of an electronic device according to some embodiments of the present disclosure. As shown in FIG. 19, an electronic device 1 includes a processor 20 and a memory 10 that are coupled to each other. At least one of the memory 10 and the processor 20 includes the three-dimensional semiconductor memory provided in any one of the foregoing embodiments.

For example, the processor 20 may include but is not limited to a central processing unit (CPU), a graphics processing unit (GPU), and the like. The memory 10 may be configured to store data to be processed by the processor 20 and/or data processed by the processor.

For example, the electronic device 1 includes but is not limited to a mobile phone, a tablet computer, a smart wristband, a wearable electronic device, a virtual reality device, an augmented reality device, an on-board device, a server, and a workstation.

The three-dimensional semiconductor memory is provided in the embodiments of the present disclosure, including: the substrate; the multiple active layers located on the substrate, where the multiple active layers are arranged in an array on the substrate; the multiple bit lines, where each of the multiple bit lines is connected to one end of each of the active layers, the multiple bit lines extend in the second direction, and the multiple bit lines are stacked on the substrate in the third direction; and the shielding structure, where the shielding structure includes the body portion and the multiple shielding portions, the shielding portions extend in the second direction, the body portion and the shielding portions each are formed of a conductive material, and the body portion is electrically connected to the shielding portions. At least one shielding portion is disposed between adjacent bit lines in the third direction. In the embodiments of the present disclosure, the shielding portions are formed between stacked bit lines. The shielding portions are electrically connected to the body portion, and are connected to the fixed potential end by means of the body portion, so as to implement electrical isolation between the stacked bit lines, reduce the parasitic capacitance between the bit lines, and further reduce signal interference between adjacent bit lines, thereby improving overall electrical performance of a stacked device.

The foregoing descriptions are merely specific implementations of the present disclosure, but are not intended to limit the protection scope of the present disclosure. Any variation or replacement readily figured out by a person skilled in the art within the technical scope disclosed in the present disclosure shall fall within the protection scope of the present disclosure. Therefore, the protection scope of the present disclosure shall be subject to the protection scope of the claims.

What is claimed is:

1. A three-dimensional semiconductor memory, comprising:
a substrate;
a plurality of active layers arranged in an array on the substrate in a second direction and a third direction;
a plurality of bit lines extending in the second direction and stacked on the substrate in the third direction, the bit line connected to one end of the active layer in a first direction;
a plurality of storage nodes, the storage node connected to the other end of the active layer in the first direction, and every two of the first direction, the second direction, and the third direction intersecting each other; and
a shielding structure comprising a body portion and a plurality of shielding portions, the plurality of shielding portions extending in the second direction, wherein, the body portion and the shielding portion each is formed of a conductive material and electrically connected to each other; and at least one shielding portion is disposed between adjacent bit lines in the third direction.

2. The three-dimensional semiconductor memory according to claim 1, wherein there is an overlapping part between a projection of each of the shielding portions on the substrate and a projection of each of the bit lines on the substrate, a length of the overlapping part is d1 in the first direction, a length of each of the bit lines in the first direction is d2, and d1 is greater than or equal to d2/2.

3. The three-dimensional semiconductor memory according to claim 1, wherein in the third direction, a thickness of each of the shielding portions is less than or equal to a thickness of each of the bit lines.

4. The three-dimensional semiconductor memory according to claim 1, wherein in the second direction, a length of each of the shielding portions is greater than or equal to a length of each of the bit lines.

5. The three-dimensional semiconductor memory according to claim 1, wherein in the second direction, a length of the body portion is less than or equal to the length of each of the bit lines.

6. The three-dimensional semiconductor memory according to claim 1, wherein the plurality of shielding portions are respectively arranged on two opposite sides of the body portion in the first direction.

7. The three-dimensional semiconductor memory according to claim 1, wherein a cross-section of the body portion on the plane where the first direction and the third direction are located is U-shaped.

8. The three-dimensional semiconductor memory according to claim 1, wherein the body portion and the plurality of shielding portions are integrated.

9. The three-dimensional semiconductor memory according to claim 1, wherein a second dielectric layer is disposed between the bit lines and the body portion; and
a first dielectric layer and the second dielectric layer are disposed between the bit lines and the shielding portions.

10. The three-dimensional semiconductor memory according to claim 9, wherein a material of the first dielectric layer is at least one of silicon oxide, silicon nitride, silicon oxynitride, and a low-k dielectric material; and,
a material of the second dielectric layer is at least one of silicon oxide, silicon nitride, silicon oxynitride, and a low-k dielectric material.

11. The three-dimensional semiconductor memory according to claim 1, wherein the conductive material comprises at least one of Ti, Ta, W, Cu, Al, TiN, and TaN.

12. The three-dimensional semiconductor memory according to claim 5, wherein the body portion comprises a plurality of sub-body portions extending in the third direction and arranged at intervals in the second direction.

13. The three-dimensional semiconductor memory according to claim 1, wherein an insulating dielectric layer is disposed between the body portion and the substrate.

14. The three-dimensional semiconductor memory according to claim 1, wherein each of the storage nodes comprises at least one of a capacitor, a phase change memory, and a resistive memory.

15. The three-dimensional semiconductor memory according to claim 1, wherein the three-dimensional semiconductor memory further comprises:
a plurality of word lines extending in the third direction, the plurality of word lines respectively corresponding to the plurality of active layers stacked in the third direction.

16. An electronic device, comprising:
a processor; and
a memory, the memory coupled to the processor, and at least one of the memory and the processor comprising the three-dimensional semiconductor memory according to claim 1.
